(19) United States
(12) Patent Application Publication
(10) Pub. No.: US 2026/0135506 A1
(43) Pub. Date: May 14, 2026

(54) Motor Driver And Method For Using The Motor Driver

(71) Applicant: Siemens Aktiengesellschaft, München (DE)

(72) Inventors: Qing Li Huang, Nanjing (CN); Peng Cheng Li, Shenzhen (CN); Xiao Long Chen, Nanjing (CN); Yan Hua Lu, Nanjing (CN)

(73) Assignee: Siemens Aktiengesellschaft, München (DE)

(21) Appl. No.: 19/121,246

(22) PCT Filed: Oct. 17, 2022
(86) PCT No.: PCT/CN2022/125650

§ 371 Date: Apr. 15, 2025

(51) Int. Cl. H02P 29/024; G01R 31/34; H02P 23/14

(52) U.S. Cl. CPC H02P 29/024; G01R 31/343; H02P 23/14

(57) ABSTRACT

Various embodiments of the teachings herein include a motor driver. An example includes: a motor driver main body with a control unit electrically connected to a power supply system; a grounding circuit electrically connected with a DC bus negative pole of the motor driver main body and including a sampling resistance; and a sampling circuit including two sampling ends and an output end. The two sampling ends are electrically connected at opposite ends of the sampling resistance to collect a voltage on the sampling resistance. The output end is electrically connected to the control unit to provide collected voltage to the control unit. The control unit determines a grounding type of the power supply system based on the collected voltage on the sampling resistance.

### CROSS-REFERENCE TO RELATED APPLICATIONS

This application is a U.S. National Stage Application of International Application No. PCT/CN2022/125650 filed Oct. 17, 2022, which designates the United States of America, the contents of which are hereby incorporated by reference in their entirety.

### TECHNICAL FIELD

The present disclosure relates to industrial technologies. Various embodiments of the teachings herein include motor drivers and methods for using a motor driver.

### BACKGROUND

Motor drivers have certain limitations when used in different power supply systems. For example, when a motor driver is used for IT grid (Here, “I” indicates that the power phase conductor is insulated against the ground, and “T” indicates that the conductive enclosure of the electrical device is grounded), the Y capacitor of internal grounding needs to be removed. Another example is that the voltage of the triangle grounded grid should be lower than that of the triangle ungrounded grid, otherwise insulation failure may be occur. Current motor drivers cannot identify the grounding type of the power supply system.

### SUMMARY

Teachings of the present application include motor drivers and methods for using a motor driver to identify the grounding type of the power supply system. For example, some embodiments of the teachings include a motor driver comprising: a motor driver main body with a control unit, electrically connected with a power supply system; a grounding circuit, electrically connected with DC bus negative pole of the motor driver main body, and includes a sampling resistance; a sampling circuit including two sampling ends and an output end, and the two sampling ends are electrically connected at both ends of the sampling resistance to collect a voltage on the sampling resistance, the output end is electrically connected with the control unit to provide collected voltage on the sampling resistance to the control unit; the control unit is configured to determine grounding type of the power supply system according to the collected voltage on the sampling resistance.

As another example, some embodiments include a method for using the motor driver including: electrifying the grounding circuit after the motor driver main body is powered on and before the drive motor runs; collecting, by a sampling circuit, a voltage on the sampling resistance in the grounding circuit and sending collected voltage on the sampling resistance to the control unit; determining, by the control unit, the grounding type of the power supply system according to the collected voltage on the sampling resistance.

It these embodiments, before the motor runs, the negative pole DCN of the DC bus of the motor driver is grounded through the grounding circuit including a sampling resistance, the sampling circuit collects the voltage on the sampling resistance and sends it to the control unit of the motor driver, according to the average value of the voltage, the control unit can determine that the type of the power supply system is grounded power supply system or ungrounded or high impedance grounded power supply system. For the power supply system that needs grounding, the grounding type of the power supply system can be determined according to the frequency of the AC component in the voltage, which realizes the identification of the grounding type of the power supply system.

In addition, after identifying the grounding type, the safety and reliability of the product are improved by further determining whether the motor driver matches the grounding type and giving an alarm when the motor driver does not match the grounding type.

In addition, after identifying that the grounding type of the power supply system is triangle power grid corner grounding, the average voltage on the DC bus can be compared with a set allowable voltage threshold to determine whether the voltage of the power supply system exceeds an allowable voltage, and an alarm is sent and a switch opening signal is inputted when the power supply system exceeds the allowable voltage, thus the safety and reliability of the product is further improved.

### BRIEF DESCRIPTION OF THE DRAWINGS

For a better understanding of the present application, reference should be made to the Detailed Description below, in conjunction with the following drawings in which like reference numerals refer to corresponding parts throughout the figures. In the drawings:

FIG. 1 is a schematic diagram illustrating an example motor driver incorporating teachings of the present disclosure;

FIG. 2 is a schematic diagram illustrating a typical voltage of a sampling resistor incorporating teachings of the present disclosure;

FIG. 3 is a flow diagram illustrating an example method for using the motor driver shown in FIG. 1 incorporating teachings of the present disclosure.

The reference numerals are as follows:

| Reference numeral | Object |
|---|---|
| CU | Control unit |
| 1 | Motor driver main body |
| AD | Sampling circuit |
| R1 | Sampling resistance |
| K1 | Control switch |
| R2 | Voltage dividing resistance |
| 2 | Power supply system |
| M | Motor |
| DCP | DC bus positive pole |
| DCN | DC bus negative pole |
| Rg | Grounding loop resistance |
| 3 | The voltage of R1when the grounding |
| | type of the power supply system is Y- |
| | type power grid midpoint grounding and |
| | the Rg = 4 ohm |
| 4 | The voltage of R1when the grounding |
| | type of the power supply system is |
| | triangular power grid angle grounding |
| | and the Rg = 4 ohm |
| 5 | The voltage of R1when the grounding |
| | type of the power supply system is Y- |
| | type power grid midpoint grounding and |
| | the Rg = 1M ohm |
| 6 | The voltage of Rlwhen the grounding |
| | type of the power supply system is |
| | triangular power grid angle grounding |
| | and the Rg = 1M ohm |
| 31~33, 331~337 | Processes |

### DETAILED DESCRIPTION

In order to identify the grounding type of the power supply system, before the motor runs, the negative pole DCN of the DC bus is grounded through a sampling resistance and other components, for instance, a voltage dividing resistance and a control switch. A sampling circuit may collect the voltage on the sampling resistance and then send collected voltage to a control unit of the motor driver. After the control unit processes the collected voltage in a certain way, it can determine the grounding type and grounding loop resistance of the power grid.

Reference will now be made in detail to examples, which are illustrated in the accompanying drawings. In the following detailed description, numerous specific details are set forth to provide a thorough understanding of the present disclosure. Also, the figures are illustrations of an example, in which assemblies shown in the figures are not necessarily essential for implementing the present application. In other instances, well-known assemblies, components, and circuits have not been described in detail so as not to unnecessarily obscure aspects of the examples.

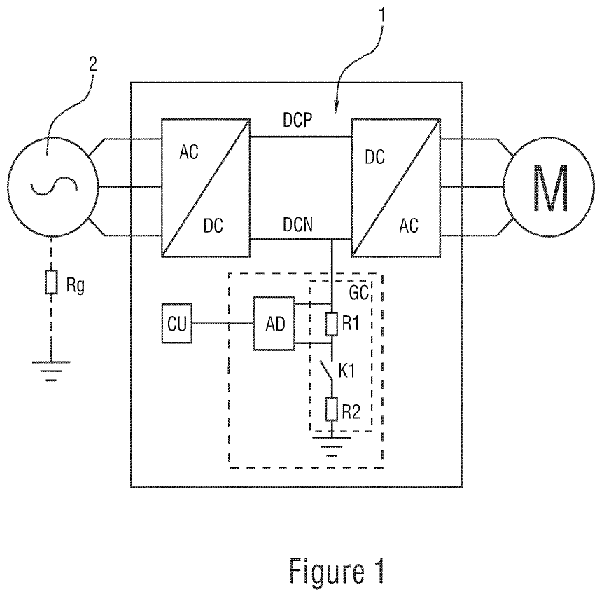

FIG. 1 is a schematic diagram illustrating an example motor driver incorporating teachings of the present disclosure. As shown in FIG. 1, the motor driver may include a motor driver main body 1 with a control unit CU, a sampling circuit AD and a grounding circuit GC.

One end of the motor driver main body 1 is electrically connected with a power supply system 2, and the other end is electrically connected with the drive motor M to control the rotation angle and running speed of the drive motor M. The motor driver main body 1 is provided with a DC bus positive pole DCP and a DC bus negative pole DCN. The power supply system 2 includes a grounding loop resistance Rg.

The grounding circuit GC is electrically connected with the DC bus negative pole DCN of the motor driver main body 1 and includes a sampling resistance R1. In this embodiment, the grounding circuit GC can also include a control switch K1 and a voltage dividing resistance R2. Of course, in other embodiments, the grounding circuit GC may have other implementations, which are not listed here.

The sampling resistance R1, the control switch K1, and the voltage dividing resistance R2 are connected in series in turn. The non-series connection end of the sampling resistance R1 is connected to the DC bus negative pole DCN of the motor driver main body 1, and the non-series connection end of the voltage dividing resistance R2 is grounded.

The control switch K1 is used to close after the motor driver main body 1 is powered on and before the drive motor M runs. At this time, the sampling resistance R1, the voltage dividing resistance R2 and the grounding loop resistance Rg share the voltage between the DC bus negative pole DCN and the grounding point of the power supply system 2.

The sampling circuit AD includes two sampling ends and an output end, and the two sampling ends are electrically connected at both ends of the sampling resistance R1 to collect the voltage on the sampling resistance R1, the output end is electrically connected with the control unit CU of the motor driver main body 1, and is used to provide collected voltage on the sampling resistance R1 to the control unit CU.

The control unit CU is used to determine the type and the grounding type of the power supply system 2 according to the voltage on the sampling resistance R1 collected by the sampling circuit AD.

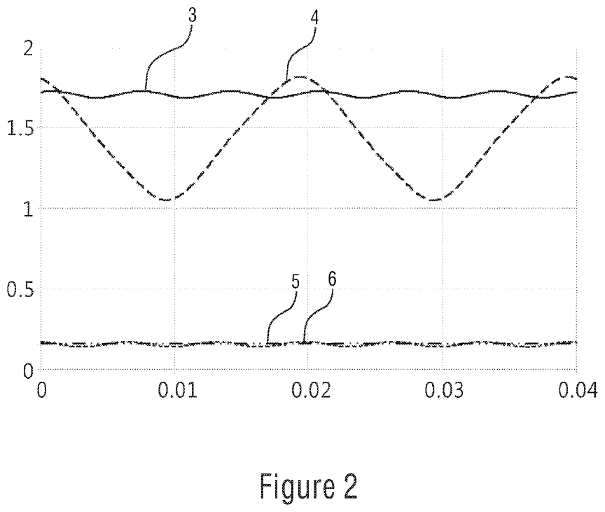

FIG. 2 is a schematic diagram illustrating a typical voltage of a sampling resistor incorporating teachings of the present disclosure. As shown in FIG. 2, in the case of the same grounding loop resistance Rg, the amplitudes and frequencies of the AC components superimposed on the DC components of the voltages on the sampling resistance R1 corresponding to different grounding types are different. For example, when the grounding loop resistance Rg is 4 ohms, the amplitude of the AC component of the voltage 3 on the sampling resistance R1 corresponding to Y-type power grid midpoint grounding is small, and the frequency of that is high, for example, it is usually three times the fundamental frequency of the power grid. That is, for a power grid with a fundamental frequency of 50 Hz, the frequency of the AC component of the voltage 3 on the sampling resistance R1 corresponding to Y-type power grid midpoint grounding is 150 Hz. For the power grid with a fundamental frequency of 60 Hz, the frequency of the AC component of the voltage 3 on the sampling resistance R1 corresponding to Y-type power grid midpoint grounding is 180 Hz. The amplitude of the AC component of voltage 4 on the sampling resistor R1 corresponding to the triangle power grid corner grounding is large and the frequency of that is low, such as the fundamental frequency of the power grid. That is, for a power grid with fundamental frequency of 50 Hz, the frequency of the AC component of voltage 4 on the sampling resistor R1 corresponding to the triangle power grid corner grounding is 50 Hz. For a power grid with fundamental frequency of 60 Hz, the frequency of the AC component of voltage 4 on the sampling resistor R1 corresponding to the triangle power grid corner grounding is 60 Hz.

In addition, when the grounding loop resistance Rg is large enough, that is, when the power supply system is ungrounded or grounded with high impedance, the voltage on the sampling resistance R1 will become small enough. As shown in FIG. 2, when the grounding loop resistance Rg is 1M ohm, the voltage 5 on the sampling resistance R1 corresponding to the Y-type power grid midpoint grounding and the voltage 6 on the sampling resistance R1 corresponding to the triangular power grid corner grounding are very low.

Based on this, in this embodiment, when the control unit CU determines the type of the power supply system 2 and grounding type thereof according to the voltage on the sampling resistance R1, it may specifically include:

The control unit CU may calculate the average voltage on the sampling resistance R1 according to the voltage on the sampling resistance R1 and compare the average voltage on the sampling resistance R1 with a preset first voltage threshold.

When the average voltage on the sampling resistance R1 is greater than the first voltage threshold, the control unit CU may determine that the power supply system 2 is a grounding power grid, and then determine the frequency of the AC component superimposed on the DC component in the voltage on the sampling resistance R1, and determine a grounding type of the power supply system 2 according to the frequency of the AC component. For example, when the frequency of the AC component is the fundamental frequency of the power grid, it is determined that the grounding type of the power supply system 2 is triangular power grid corner grounding. When the frequency of the AC component is three times of the fundamental frequency of the power grid, that is, the AC component is the third harmonic of the fundamental wave of the power grid, it is determined that the grounding type of the power supply system 2 is Y-type power grid midpoint grounding.

Furthermore, after identifying the grounding type of the power supply system, the control unit CU may further determine whether the motor driver matches the grounding type. When the motor driver doesn't match the grounding type, the control unit CU may send an alarm signal in time to improve the safety and reliability of the product.

In addition, the control unit CU may further determine whether the voltage of the power supply system 2 exceeds an allowable voltage by comparing the average voltage on the DC bus with a preset allowable voltage threshold after identifying that the grounding type of the power supply system 2 is triangular power grid corner grounding. When the average voltage on the DC bus exceeds the allowable voltage threshold, the control unit CU may determine that the voltage of the power supply system 2 exceeds the allowable voltage. Furthermore, an alarm signal may be sent out in time.

When the average voltage on the sampling resistance R1 is not greater than the first voltage threshold, the control unit CU may compare the average voltage on the sampling resistance R1 with a preset second voltage threshold. The first voltage threshold is greater than the second voltage threshold. When the average voltage on the sampling resistance R1 is less than the second voltage threshold, the control unit CU may determine that the power supply system 2 is an IT power grid, and the grounding type of the IT power grid is ungrounded or grounded with high impedance.

Furthermore, the control unit CU may further calculate the grounding loop resistance Rg according to the average voltage on the DC bus, the average voltage of the sampling resistance R1, and the resistance in the grounding circuit GC. For example, in this embodiment, the ground loop resistance Rg can be calculated according to the following equation (1):

$$R g = \frac{R 1 \times {U}_{avg \_ d c}}{2 {U}_{avg \_ R 1}} - R 1 - R 2 \qquad ( 1 )$$

Wherein, U_{avg_dc} is the average voltage on the DC bus, U_{avg_R1} is the average voltage on the sampling resistance R1, R1 is the sampling resistance, and R2 is the voltage dividing resistance.

The control unit CU may compare the grounding loop resistance Rg calculated in equation (1) above with a preset resistance threshold. When the grounding loop resistance Rg is greater than the resistance threshold, the control unit CU may determine that the IT power grid is not grounded or is grounded with high impedance, otherwise the control unit CU may determine that the IT power grid is abnormally grounded, and an alarm signal may be sent at this time.

If the average voltage on the sampling resistor R1 is between the first voltage threshold and the second voltage threshold, the control unit CU may determine that the power supply system 2 has an abnormal grounding, and then it may send an alarm signal. The grounding loop resistance Rg includes the resistance of the whole grounding loop, such as the grounding wire resistance and contact resistance, mainly to identify that if the grounding wire is broken, the driver will determine that the grounding is abnormal.

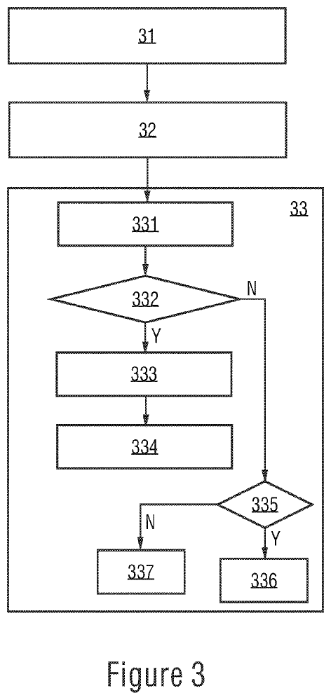

FIG. 3 is a flow diagram illustrating an example method for using the motor driver shown in FIG. 1 incorporating teachings of the present disclosure. As shown in FIG. 3, the method may include the following processes.

At block 31, after the motor driver main body 1 is powered on and before the drive motor M runs, the grounding circuit GC is electrified. For the case that the grounding circuit GC shown in FIG. 1 includes the control switch K1, the grounding circuit GC can be electrified by closing the control switch K1.

At block 32, the sampling circuit AD collects the voltage on the sampling resistance R1 and sends collected voltage on the sampling resistance R1 to the control unit CU.

At block 33, the control unit CU determines the type and grounding type of the power supply system 2 according to the voltage on the sampling resistance R1 collected by the sampling circuit AD.

In specific implementation, block 33 can further include:

At block 331, the control unit CU calculates the average voltage on the sampling resistance R1 according to the voltage on the sampling resistance R1.

At block 332, the average voltage on the sampling resistance R1 is compared with a preset first voltage threshold, when the average voltage on the sampling resistance R1 is greater than the first voltage threshold, block 333 is executed, otherwise, proceed to block 335.

At block 333, a frequency of the AC component superimposed on the DC component of the voltage on the sampling resistor R1 is determined.

At block 334, grounding type of the power supply system 2 is determined according to the frequency of the AC component.

For example, when the frequency of the AC component is the fundamental frequency of the power grid, it is determined that the grounding type of the power supply system 2 is triangular power grid corner grounding, when the frequency of the AC component is three times of the fundamental frequency of the power grid, that is, the AC component is the third harmonic of the fundamental wave of the power grid, it is determined that the grounding type of the power supply system 2 is Y-type power grid midpoint grounding.

Furthermore, after identifying the grounding type of the power supply system 2, the control unit CU may determine whether the motor driver matches the grounding type. When the motor driver doesn't match the grounding type, the control unit CU may send an alarm signal in time to improve the safety and reliability of the product.

In addition, after identifying that the grounding type of the power supply system 2 is triangular power grid corner grounding, the average voltage on the DC bus can be further compared with a set allowable voltage threshold, when the average voltage on the DC bus is greater than the set allowable voltage threshold, it is determined that the voltage of the power supply system exceeds an allowable voltage. At this time, an alarm signal may be sent in time and a switch opening signal may be inputted.

At block 335, the average voltage on the sampling resistance R1 is compared with the preset second voltage threshold. When the average voltage on the sampling resistance R1 is less than the second voltage threshold, block 336 is executed, otherwise block 337 is executed, wherein the first voltage threshold is greater than the second voltage threshold.

At block 336, it is determined that the power supply system 2 is an IT power grid, and its grounding type is ungrounded or grounded with high impedance.

Furthermore, the control unit CU may calculate the grounding loop resistance Rg according to the average voltage on the DC bus, the average voltage of the sampling resistance R1, and the resistance in the grounding circuit GC, and compare the calculated the grounding loop resistance Rg with a preset resistance threshold. If the grounding loop resistance Rg is greater than the resistance threshold, it is determined that the IT grid is ungrounded or high impedance grounded, otherwise it is determined that the IT power grid has abnormal grounding, and an alarm signal may be sent at this time.

At block 337, the control unit CU determines that the power supply system 2 has abnormal grounding and then may send out an alarm signal.

Before the motor runs, the negative pole DCN of the DC bus of the motor driver is grounded through the grounding circuit including a sampling resistance, the sampling circuit collects the voltage on the sampling resistance and sends it to the control unit of the motor driver, according to the average value of the voltage, the control unit can determine that the type of the power supply system is grounded power supply system or ungrounded or high impedance grounded power supply system. For the power supply system that needs grounding, the grounding type of the power supply system can be determined according to the frequency of the AC component in the voltage, which realizes the identification of the grounding type of the power supply system.

In addition, after identifying the grounding type, the safety and reliability of the product are improved by further determining whether the motor driver matches the grounding type and giving an alarm when the motor driver does not match the grounding type.

In addition, after identifying that the grounding type of the power supply system is triangle power grid corner grounding, the average voltage on the DC bus can be compared with a set allowable voltage threshold to determine whether the voltage of the power supply system exceeds an allowable voltage, and an alarm is sent and a switch opening signal is inputted when the power supply system exceeds the allowable voltage, thus the safety and reliability of the product is further improved.

As used herein, unless the context clearly supports exceptions, the singular forms “a” (“a”, “an”, “the”) are intended to include the plural forms. It should also be understood that, “and/or” used herein is intended to include any and all possible combinations of one or more of the associated listed items. The number of the embodiments of the present application are only used for description, and do not represent the merits of the implementations.

The foregoing description, for purpose of explanation, has been described with reference to specific examples. However, the illustrative discussions above are not intended to be exhaustive or to limit the present disclosure to the precise forms disclosed. Many modifications and variations are possible in view of the above teachings. The examples were chosen and described to explain the principles of the present disclosure and its practical applications, to thereby enable others skilled in the art to best utilize the present application and various examples with various modifications as are suited to the particular use contemplated.

What is claimed is:

1. A motor driver, comprising:
a motor driver main body with a control unit electrically connected to a power supply system;
a grounding circuit electrically connected with a DC bus negative pole of the motor driver main body and including a sampling resistance;
a sampling circuit including two sampling ends and an output end, wherein the two sampling ends are electrically connected at opposite ends of the sampling resistance to collect a voltage on the sampling resistance, and the output end is electrically connected to the control unit to provide collected voltage to the control unit;
wherein the control unit determines a grounding type of the power supply system based on the collected voltage on the sampling resistance.

2. The motor driver according to claim 1, wherein the control unit calculates an average voltage on the sampling resistance and compares the average voltage to a preset first voltage threshold; and
if the average voltage is greater than the first voltage threshold, the control unit identifies the power supply system as a grounding power grid, and then determines a grounding type of the power supply system based on a frequency of the AC component superimposed on the DC component in the voltage on the sampling resistance.

3. The motor driver according to claim 2, WHEREIN:
if the frequency of the AC component matches the fundamental frequency of the power grid, the control unit determines the grounding type of the power supply system is triangular power grid corner grounding; and
if the frequency of the AC component is three times es the fundamental frequency of the power grid, the control unit determines the grounding type of the power supply system is Y-type power grid midpoint grounding.

4. The motor driver according to claim 3, wherein the control unit further-compares an average voltage on the DC bus with a preset allowable voltage threshold after determining that the grounding type of the power supply system is triangular power grid corner grounding, and if the average voltage on the DC bus exceeds the allowable voltage threshold, the control unit determines the voltage of the power supply system exceeds the allowable voltage.

5. The motor driver according to claim 3, wherein the control unit determines whether the motor driver matches the grounding type, and if the motor driver doesn't match the grounding type, the control unit sends an alarm signal.

6. The motor driver according to claim 2, wherein:
if the average voltage on the sampling resistance is not greater than the first voltage threshold, the control unit compares the average voltage with a preset second voltage threshold; and
if the average voltage on the sampling resistance is less than the second voltage threshold, the control unit identifies the power supply system as an IT power grid, and the grounding type of the IT power grid is ungrounded or grounded with high impedance;
wherein the first voltage threshold is greater than the second voltage threshold.

7. The motor driver according to claim 6, wherein:
the power supply system includes a grounding loop resistance; and
the control unit calculates the grounding loop resistance according to an average voltage on the DC bus, the average voltage of the sampling resistance, and the resistance in the grounding circuit;
then the control unit compares calculated grounding loop resistance with a preset resistance threshold; and
if the grounding loop resistance is greater than the resistance threshold, the control unit determines that the IT power grid is not grounded or is grounded with high impedance, otherwise the control unit determines that the IT power grid is abnormally grounded.

8. The motor driver according to any claim 1, wherein:
the grounding circuit further includes a control switch and a voltage dividing resistance; and
the control switch and the voltage dividing resistance are connected in series in turn with the sampling resistance.

9. A method for using a motor driver, the method comprising:
electrifying a grounding circuit after a motor driver main body is powered on and before the drive motor runs;
collecting, with a sampling circuit, a voltage on a sampling resistance in the grounding circuit and sending the collected voltage on the sampling resistance to the control unit;
determining, with the control unit, a grounding type of the power supply system according to the collected voltage on the sampling resistance.

10. The method for using the motor driver according to claim 9, wherein determining the grounding type of the power supply system according to the voltage on the sampling resistance (R1) comprises:
calculating, with the control unit, an average voltage on the sampling resistance according to the collected voltage on the sampling resistance;
comparing the average voltage on the sampling resistance to a preset first voltage threshold;
if the average voltage is greater than the first voltage threshold, determining a grounding type of the power supply system based on a frequency of an AC component superimposed on a DC component of the voltage on the sampling resistor.

11. The method for using the motor driver according to claim 10, wherein determining, by the grounding type of the power supply system further comprises:
if the average voltage on the sampling resistance R1 is not greater than the first voltage threshold, comparing, using the control unit, the average voltage to a preset second voltage threshold;
if the average voltage on the sampling resistance is less than the second voltage threshold, determining, using the control unit, the power supply system is an IT power grid, and grounding type of the IT power grid is ungrounded or grounded with high impedance.
